(19) United States
(12) Patent Application Publication
(10) Pub. No.: US 2023/0326705 A1
(43) Pub. Date: Oct. 12, 2023

(54) PROCESSING APPARATUS AND METHOD OF MANUFACTURE

(71) Applicant: Taiwan Semiconductor Manufacturing Company Limited, Hsin-Chu (TW)

(72) Inventor: Chansyun David YANG, Shinchu (TW)

(21) Appl. No.: 17/716,010

(22) Filed: Apr. 8, 2022

(51) Int. Cl. H01J 37/147; H01J 37/08; H01J 37/305; H01J 37/02; H01L 21/311; H01L 21/8234; H01L 29/66

(52) U.S. Cl. CPC H01J 37/1471; H01J 37/08; H01J 37/3056; H01J 37/026; H01L 21/31116; H01L 21/823431; H01L 29/66545; H01J 2237/1506; H01J 2237/3343

(57) ABSTRACT

An ion beam processing tool includes a plasma source, a grid arrangement positioned proximate the plasma source to generate an ion beam, a beam deflector positioned adjacent the grid arrangement, and a controller configured to control the beam deflector to deflect the ion beam to generate a tilted ion beam. A method includes generating an ion beam, directing the ion beam at a target, deflecting the ion beam in a first direction to remove a first portion of material from the target, and deflecting the ion beam in a second direction different than the first direction to remove a second portion of material from the target.

### BACKGROUND

Processing tools are used in the semiconductor industry to perform various processes to fabricate devices. A plasma tool generates an ion beam that may be used to deposit material on a substrate or to remove material from the substrate. Semiconductor fabrication has progressed into nanometer technology process nodes in pursuit of higher device density, higher performance, and lower costs, challenges from both fabrication and design issues have resulted in the development of three dimensional designs, such as gate all around (GAA) transistors. A GAA transistor comprises one or more nano-sheet or nano-wire channel regions having a gate wrapped around the nano-sheet or nano-wire. GAA transistors can reduce short channel effect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are simplified diagrams of an ion beam processing tool, in accordance with some embodiments.

FIGS. 2A-2C are simplified diagrams of a pathway for an ion beamlet through a single aperture set in the grid arrangement, in accordance with some embodiments.

FIGS. 3A-3H are illustrations of a semiconductor structure at various stages of fabrication, in accordance with some embodiments.

FIGS. 4A-4C illustrate a phased removal, in accordance with some embodiments.

FIG. 5 is an illustration of an exemplary computer-readable medium, according to some embodiments.

FIG. 6 illustrates an example computing environment wherein one or more of the provisions set forth herein may be implemented, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An ion beam processing tool and one or more techniques for fabricating a semiconductor structure using the ion beam processing tool are provided herein. In some embodiments, the ion beam processing tool includes a plasma source and a grid arrangement positioned proximate the plasma source to generate an ion beam. A beam deflector is positioned adjacent the grid arrangement to deflect the ion beam to facilitate a tilted material removal process. A semiconductor structure includes a first nanostructure, such as a nanosheet transistor or nanowire transistor, and a second nanostructure. A spacer is between the first nanostructure and the second nanostructure. During a gate replacement process, the tilted material removal process is used to remove sidewall portions of the spacer to widen the gate cavity and provides a more flexible process window for forming the metal replacement gate.

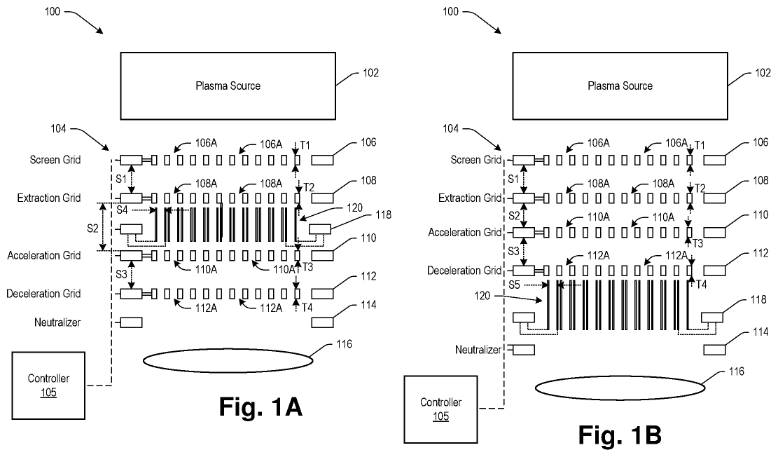

FIGS. 1A and 1B are simplified diagrams of an ion beam processing tool 100, in accordance with some embodiments. The ion beam processing tool 100 comprises a plasma source 102 for generating plasma, a grid arrangement 104 that generates an ion beam from the plasma, and a controller 105 that controls operating parameters of the ion beam processing tool 100. The plasma source 102 comprises a vacuum chamber, a radio frequency (RF) coil, a gas inlet line, and an exit port. The field generated by the RF coil ionizes the gas supplied through the gas inlet to generate a plasma. The grid arrangement 104 is provided at the exit port to extract ions from the plasma to generate an ion beam. In some embodiments, the grid arrangement 104 comprises multiple grids, such as a screen grid 106, an extraction grid 108, an acceleration grid 110, and a deceleration grid 112. The screen grid 106 and the extraction grid 108 pull ions from the plasma and control the ion current density. In some embodiments, the voltage applied to the screen grid 106 is about between 1.5 kV and 1.8 kV or between about 1.2 kV and 1.5 kV, and the voltage applied to the extraction grid 108 is about between 500 V and 1300 V or between about 800 V and 1000 V. The bias between the extraction grid 108 and the acceleration grid 110 controls the ion beam energy. In some embodiments, the voltage applied to the acceleration grid 110 is about between 0 V and −400 V or between about −100 V and −300 V. The deceleration grid 112 decelerates the ions to reduce the divergence of the exiting ion beams. In some embodiments, the voltage applied to the deceleration grid 112 is ground or 0 V. In some embodiments, a neutralizer 114 is provided at an exit of the grid arrangement 104. The neutralizer 114 injects electrons for current and space charge neutralization of the ion beam. Other structures and configurations of the grid arrangement 104 are within the scope of the present disclosure. For example, the grid arrangement 104 may include additional grids or fewer grids. The controller 105 sets the voltages applied to the grid arrangement 104 and the configuration of the neutralizer 114.

For ease of illustration, the grid arrangement 104 is illustrated in expanded form in FIGS. 1A and 1B, greatly increasing the distance between each grid 106, 108, 110, 112. Each grid 106, 108, 110, 112 is illustrated in cross section. Each grid 106, 108, 110, 112 comprises a pattern of apertures 106A, 108A, 110A, 112A through a surface of the grid 106, 108, 110, 112 to allow ions to pass through the grid 106, 108, 110, 112 and impinge upon a target 116. In some embodiments, the target 116 is a semiconductor wafer. In the grid arrangement 104, the apertures 106A, 108A, 110A, 112A of each grid 106, 108, 110, 112 are substantially aligned or coaxial with the apertures 106A, 108A, 110A, 112A of the other grids 106, 108, 110, 112 such as to create columnar paths through the grid arrangement 104. Within a grid 106, 108, 110, 112, multiple apertures 106A, 108A, 110A, 112A are present. The dimensions of the apertures 106A, 108A, 110A, 112A may vary at least one of between grids 106, 108, 110, 112 or across the surface of a grid 106, 108, 110, 112. In some embodiments, the apertures 106A, 108A, 110A, 112A have a circular cross-sectional shape. The apertures 106A of the screen grid 106 may be between about 1-10 mm or between about 4-7 mm, and the screen grid 106 may have a thickness, T1, of about 0.1-1 mm or about 0.3-0.8 mm. The apertures 108A of the extraction grid 108 may be between about 1-8 mm or between about 2-5 mm, and the extraction grid 108 may have a thickness, T2, of about 0.1-3 mm or about 0.4-1.0 mm. A diameter delta, representing the difference between the diameter of the apertures 106A of the screen grid 106 and the diameter of the apertures 108A of the extraction grid 108 is between about 0.1-6 mm or between about 0.5-4 mm. The apertures 110A of the acceleration grid 110 may be between about 1-9 mm or between about 2-6 mm, and the acceleration grid 110 may have a thickness, T3, of about 0.1-2 mm or about 0.3-1.2 mm. The apertures 112A of the deceleration grid 112 may be between about 1-9 mm or between about 3-7 mm, and the deceleration grid 112 may have a thickness, T4, of about 0.1-1.2 mm or about 0.5-0.7 mm. A diameter delta, representing the difference between the diameter of the apertures 110A of the acceleration grid 110 and the diameter of the apertures 112A of the deceleration grid 112 is between about 0.1-6 mm or between about 0.5-4 mm. The diameters delta parameters are provided to control the ion beamlet shape and beam focus. At least one of the thickness of individual grids 106, 108, 110, 112, or the spacing, S1, S2, S3 between the grids 106, 108, 110, 112 may vary to obtain a required beam profile and beam energy level. The spacing, S1, between the screen grid 106 and the extraction grid 108 may be about 0.1-0.9 mm or about 0.4-0.6 mm. The spacing, S2, between the extraction grid 108 and the acceleration grid 110 may be about 15-60 mm or about 25-45 mm. The spacing, S3, between the acceleration grid 110 and the deceleration grid 112 may be about 0.2-1 mm or about 0.5-0.7 mm. The ion beam exiting the ion beam processing tool 100 is the summation of individual ion beamlets generated by each set of apertures 106A, 108A, 110A, 112A.

According to some embodiments, a beam deflector 118 is positioned within the grid arrangement 104. The beam deflector 118 comprises a plurality of plates 120 positioned along the columnar paths defined by the apertures 106A, 108A, 110A, 112A of the grids 106, 108, 110, 112. A bias voltage applied across the plates 120 of the beam deflector 118 by the controller 105 causes deflection of the ion beam to generate a tilted ion beam. In some embodiments, the tilted ion beam is used for directional etching of features defined on the target 116. As illustrated in FIG. 1A, the beam deflector 118 is positioned in the grid arrangement 104 between the extraction grid 108 and the acceleration grid 110 along the path of the ion beam. In some embodiments, the plates 120 have a length of about 12-50 mm or about 22-40 mm and a spacing, S4, of about 1-12 mm or about 5-8 mm.

Referring to FIG. 1B, the beam deflector 118 is positioned in the grid arrangement 104 along the path of the ion beam after the deceleration grid 112 and before the neutralizer 114. Positioning the beam deflector 118 after the deceleration grid 112 allows the use of at least one of longer plates 120 or wider spacing. In the embodiment of FIG. 1B, the plates 120 have a length of about 30-90 mm or about 40-80 mm and a spacing, S5, of about 4-12 mm or about 7-9 mm.

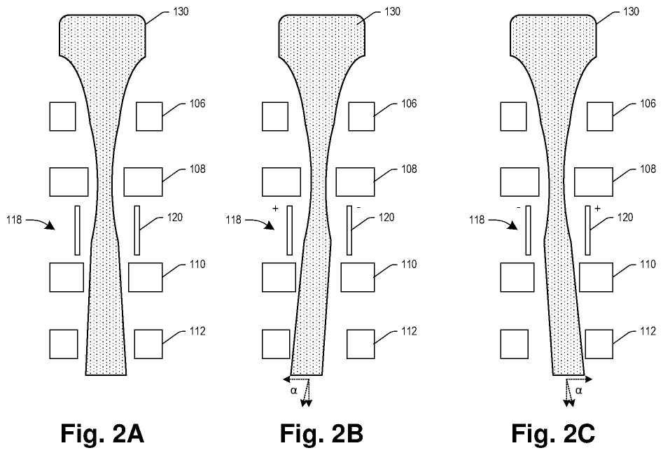

FIGS. 2A-2C are simplified diagrams of a pathway for an ion beamlet 130 through a single aperture set in the grid arrangement 104, in accordance with some embodiments. The configuration of FIG. 1A is illustrated in FIGS. 2A-2C, but the description also applies to the configuration of FIG. 1B. In FIG. 2A, no bias is applied to the plates 120 of the beam deflector 118, and the path of the ion beamlet 130 is unaffected. In FIG. 2B, a positive bias is applied to the plates 120 of the beam deflector 118, and the path of the ion beamlet 130 is tilted toward the plate 120 with the positive charge (i.e., the plate 120 on the left). In FIG. 2C, a negative bias is applied to the plates 120 of the beam deflector 118, and the path of the ion beamlet 130 is tilted toward the plate 120 with the positive charge in a direction opposite to the direction in FIG. 2B (i.e., the plate 120 on the right). Controlling the amount of bias applied to the plates 120 of the beam deflector 118 determines the degree of tilt. In some embodiments, the spacing S4, S5 between the plates 120 and the position of the plates 120 in the grid arrangement 104 affects the degree of tilt angle control. In some embodiments, the beam deflector 118 generates a tilt angle, a, of about 75°-92° or about 80°-87°.

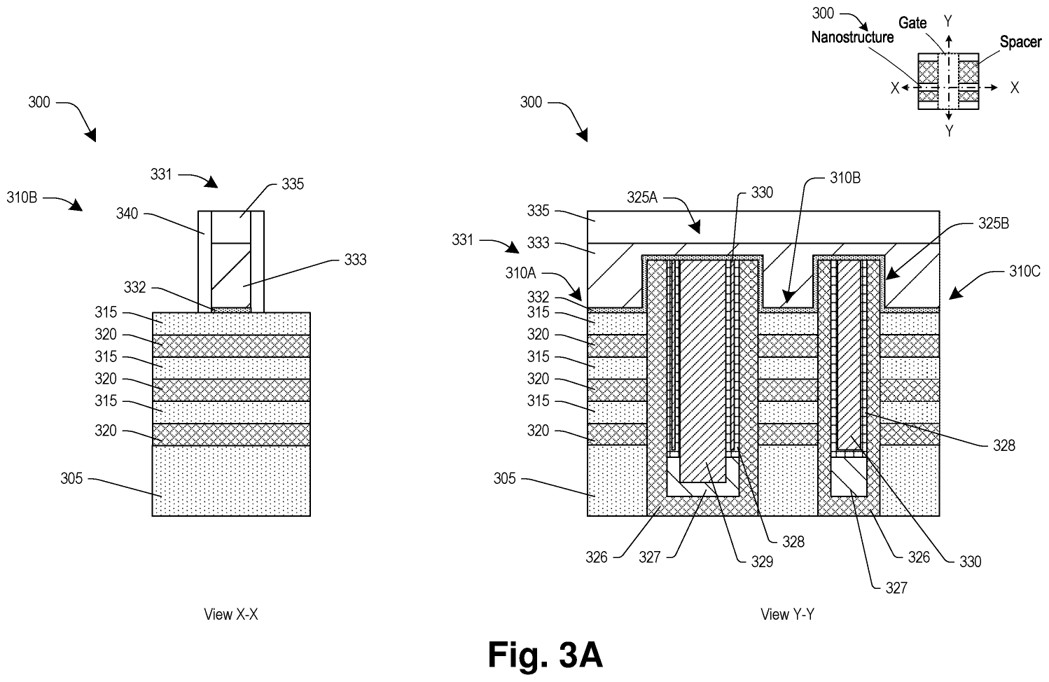

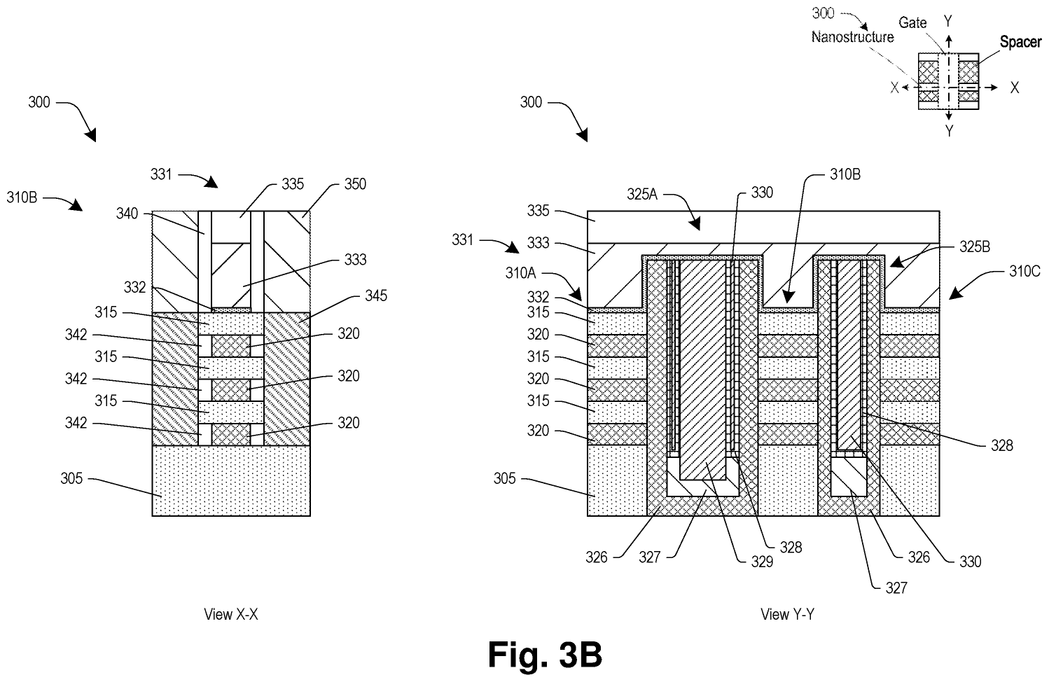

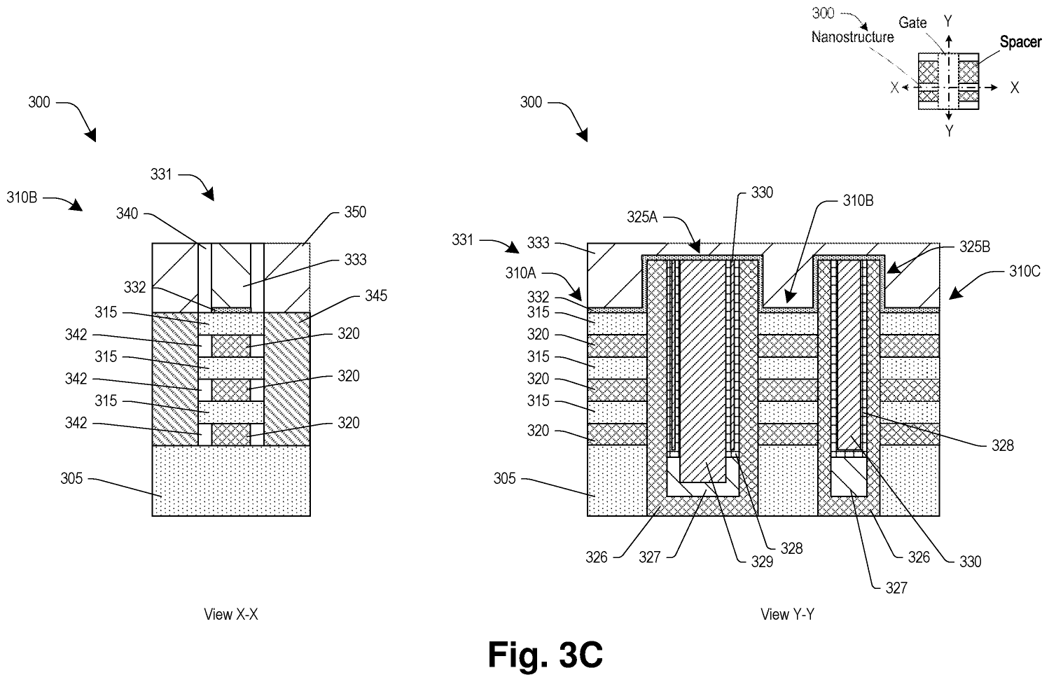

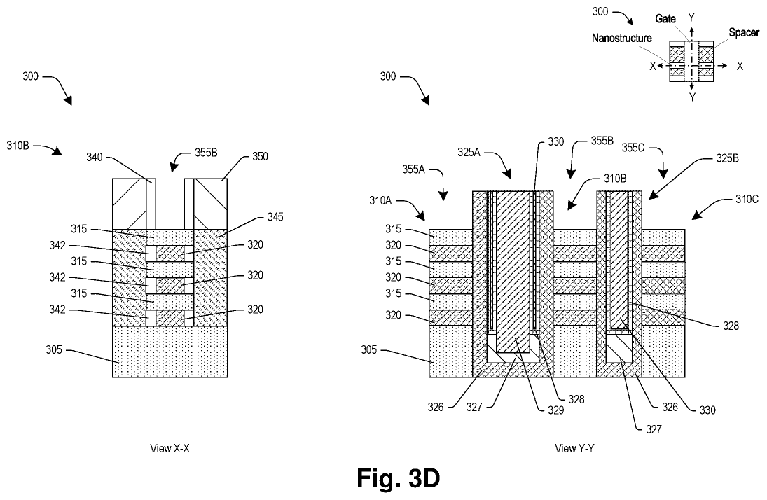

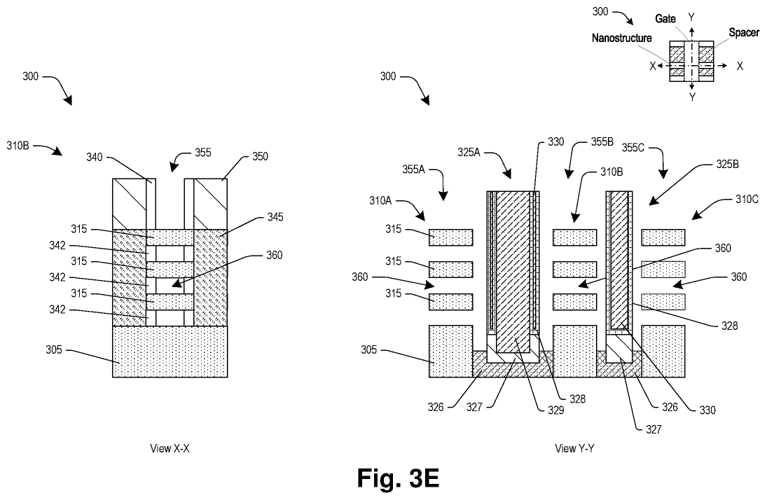

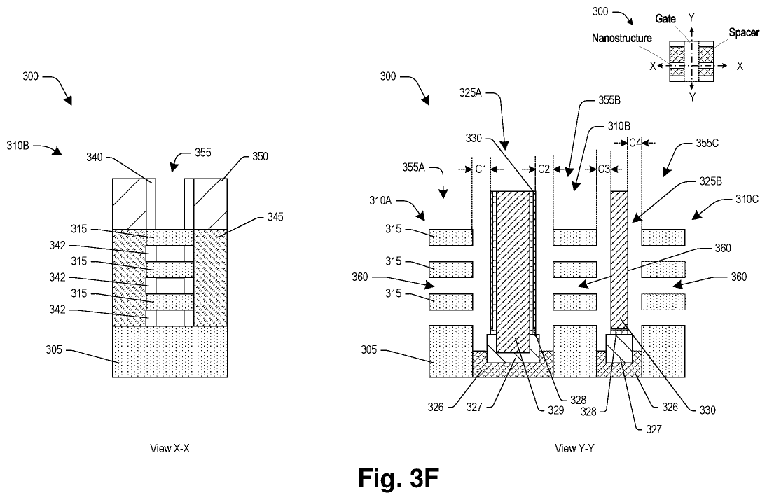

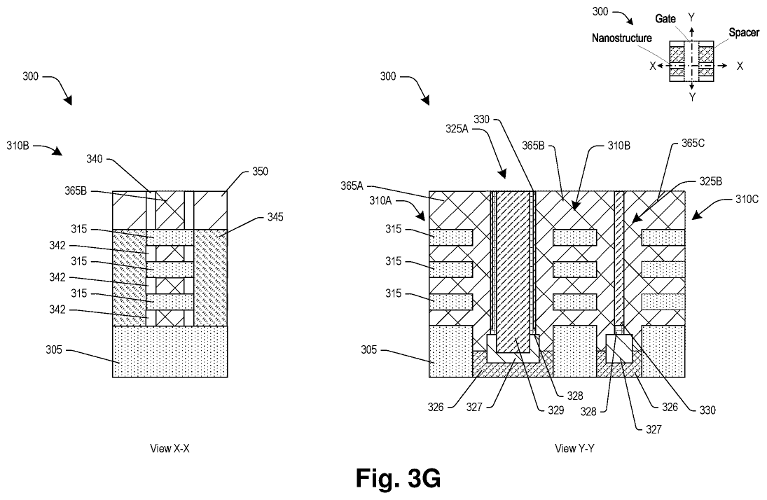

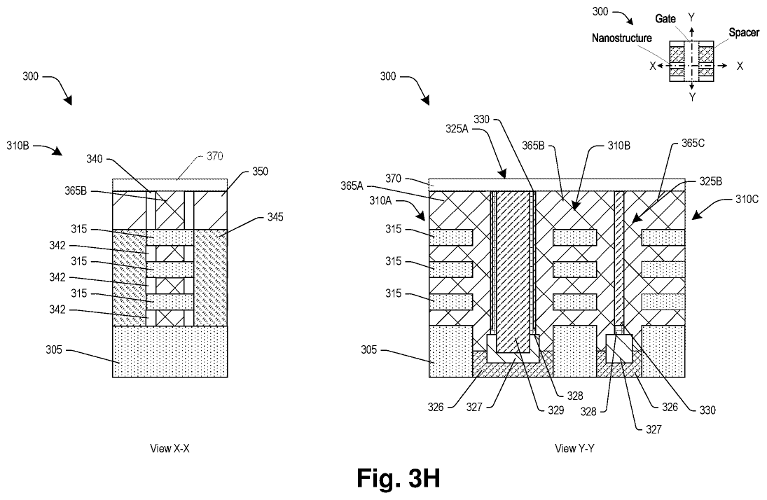

FIGS. 3A-3H are illustrations of a semiconductor structure 300 at various stages of fabrication, in accordance with some embodiments. FIGS. 3A-3H include a simplistic plan view showing where various cross-sectional views are taken. Referring to FIG. 3A, the view X-X is a cross-sectional view taken through the semiconductor structure 300 in a direction corresponding to a direction through a nanostructure, and the view Y-Y is a cross-sectional view taken through the semiconductor structure 300 in a direction corresponding to a gate length direction through gate structures. Not all aspects of the processing shown in the cross-sectional views will be depicted in the plan view.

Referring to FIG. 3A, a plurality of layers used in the formation of the semiconductor structure 300 are illustrated, in accordance with some embodiments. The plurality of layers is formed over a semiconductor layer 305. In some embodiments, the semiconductor layer 305 is part of a substrate comprising at least one of an epitaxial layer, a single crystalline semiconductor material such as, but not limited to Si, Ge, SiGe, InGaAs, GaAs, InSb, GaP, GaSb, InAlAs, GaSbP, GaAsSb, and InP, a silicon-on-insulator (SOI) structure, a wafer, or a die formed from a wafer. In some embodiments, the semiconductor layer 305 comprises crystalline silicon.

In some embodiments, the semiconductor structure 300 comprises nanostructure based transistors. Nanostructure is used herein to refer to substantially flat, nearly two-dimensional structures, such as sometimes referred to as nanosheets, as well as structures having two-dimensions that are similar in magnitude, such as sometimes referred to as nanowires.

In some embodiments, nanostructures 310A, 310B, 310C are formed by forming a stack of semiconductor material layers and performing an etch process to remove some of the stack of semiconductor material layers, thereby defining the nanostructures 310A, 310B, 310C. In some embodiments, the nanostructures 310A, 310B, 310C comprise semiconductor material layers 315 and sacrificial semiconductor layers 320. In some embodiments, the materials of the semiconductor material layers 315 are different than the materials of the sacrificial semiconductor layers 320 to provide etch selectivity and allow for removal of the sacrificial semiconductor layers 320.

In some embodiments, the semiconductor material layers 315 comprise the same material composition, and the sacrificial semiconductor layers 320 comprise the same material composition. In some embodiments, the semiconductor material layers 315 comprise substantially pure silicon, and the sacrificial semiconductor layers 320 comprise silicon-germanium (SiₓGe₍₁₋ₓ₎ where x ranges from 0.25 to 0.85).

In some embodiments, the number of semiconductor material layers 315 and sacrificial semiconductor layers 320 varies. In some embodiments, the order of the semiconductor material layers 315 and sacrificial semiconductor layers 320 varies. In some embodiments, thicknesses of the semiconductor material layers 315 and sacrificial semiconductor layers 320 vary, and the thicknesses need not be the same.

In some embodiments, an etch process is performed to remove some of the stack of semiconductor material layers 315 and sacrificial semiconductor layers 320 to define recesses between the nanostructures 310A, 310B, 310C and fins 325A, 325B are formed in the recesses. In some embodiments, the fins 325A, 325B have different widths. For example, the fin 325A may be wider than the fin 325B, thereby affecting the spacings between the nanostructures 310A, 310B, 310C. In some embodiments, the fin 325A comprises a cladding layer 326, a bottom liner 327, a sidewall liner 328, a center portion 329, and an inner layer 330. The fin 325B comprises the cladding layer 326, the bottom liner 327, the sidewall liner 328, and the inner layer 330. In some embodiments, the cladding layer 326 comprises the same material as the sacrificial semiconductor layers 320, for example, silicon germanium. In some embodiments, the sidewall liner 328 comprises a high-k dielectric material. As used herein, the term “high-k dielectric” refers to the material having a dielectric constant, k, greater than or equal to about 3.9, which is the k value of SiO₂. The high-k dielectric material may be any suitable material. Examples of the high-k dielectric material include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. In some embodiments, the bottom liner 327 comprises a dielectric material that is not a high-k material, such as silicon nitride, or some other suitable dielectric material.

The center portion 329 may comprise one or more layers of a low-k material. A low-k dielectric material may comprise at least one of Si, O, C, H, or N, such as SiCOH, SiOC, SiOCN, or other suitable materials. Organic material such as polymers may be used for the low-k material. In some embodiments, the low-k dielectric material comprises one or more layers of a carbon-containing material, organo-silicate glass, a porogen-containing material, or combinations thereof. The low-k material may be formed by using, for example, at least one of chemical vapor deposition (CVD), low pressure CVD (LPCVD), atomic layer CVD (ALCVD), or a spin-on technology. In some embodiments, the center portion 329 of the fin 325A comprises multiple layers due to the width of the fin 325A. The inner layer 330 may comprise the same material as the center portion 329.

In some embodiments, the cladding layer 326 is formed by depositing a layer in a trench formed to separate the nanostructures 310A, 310B, 310C. In some embodiments, the bottom liner 327 is formed by forming a layer of material of the bottom liner 327 over the cladding layer 326, and the center portion 329 is formed by filling a remaining portion of the trench with the material of the center portion 329. The cladding layer 326 300 is then planarized to remove portions of the material of the center portion 329 outside the trench. An etch process is performed to recess the material of the bottom liner 327, and the resulting recesses are filled with material of the sidewall liner 328 and the inner layer 330. The sidewall liner 328 may be a conformal layer, and the inner layer 330 may fill the remaining portions of the recess. Other structures and configurations of the fins 325A, 325B are within the scope of the present disclosure.

In some embodiments, sacrificial gate structures 331 are formed over the nanostructures 310A, 310B, 310C. In some embodiments, the sacrificial gate structures 331 comprise a first gate dielectric layer 332 and sacrificial gate electrodes 333. In some embodiments, the first gate dielectric layer 332 comprises a high-k dielectric material or other suitable dielectric material.

In some embodiments, the first gate dielectric layer 332 comprises a native oxide layer formed by exposure of the semiconductor structure 300 to oxygen at various points in the process flow, causing the formation of silicon dioxide on exposed surfaces of the nanostructures 310A, 310B, 310C. In some embodiments, an additional layer of dielectric material, such as a high-k dielectric material or other suitable material, is formed over the native oxide to form the first gate dielectric layer 332. According to some embodiments, the sacrificial gate structures 331 are formed by forming a layer of sacrificial material and a hard mask layer over the nanostructures 310A, 310B, 310C. In some embodiments, a patterning process is performed to pattern the hard mask layer corresponding to the pattern of gate structures to be formed, and an etch process is performed using the patterned hard mask layer to etch the layer of sacrificial material to define the sacrificial gate electrodes 333. In some embodiments, remaining portions of the hard mask layer form cap layers 335 over the sacrificial gate electrodes 333.

In some embodiments, a sidewall spacer 340 is formed adjacent the sacrificial gate structure 331. In some embodiments, the sidewall spacer 340 is formed by depositing a conformal spacer layer over the sacrificial gate structure 331 and performing an anisotropic etch process to remove portions of the spacer layer positioned on horizontal surfaces of the cap layers 335, and the nanostructures 310A, 310B, 310C. In some embodiments, the sidewall spacer 340 comprises the same material composition as the cap layer 335. In some embodiments, the sidewall spacer 340 comprises nitrogen and silicon or other suitable materials.

Referring to FIG. 3B, end spacers 342 are formed adjacent ends of the sacrificial semiconductor layers 320, source/drain regions 345 are formed in the nanostructures 310A, 310B, 310C, and a dielectric layer 350 is formed over the nanostructures 310A, 310B, 310C and adjacent the sacrificial gate structures 331, in accordance with some embodiments. In some embodiments, after forming the nanostructures 310A, 310B, 310C, an isotropic etch process is performed to recess the sacrificial semiconductor layers 320 to define end cavities. In some embodiments, a deposition process is performed to form a dielectric spacer layer over the nanostructures 310A, 310B, 310C, and an isotropic etch process is performed to remove portions of the dielectric spacer layer outside the end cavities to define the end spacers 342. In some embodiments, the end spacers 342 comprise the same material composition as the sidewall spacer 340.

In some embodiments, the source/drain regions 345 are formed in the nanostructures 310A, 310B, 310C after forming the sacrificial gate structures 331 and after forming the end spacers 342. In some embodiments, an epitaxial growth process is performed to form the source/drain regions 345.

In some embodiments, the dielectric layer 350 is formed over the nanostructures 310A, 310B, 310C and adjacent the sacrificial gate structures 331 after forming the source/drain regions 345. In some embodiments, a portion of the dielectric layer 350 is removed to expose the cap layers 335. In some embodiments, the dielectric layer 350 is planarized to expose the cap layers 335. In some embodiments, the dielectric layer 350 comprises silicon dioxide or a low-k material. Referring to FIG. 3C, the cap layers 335 are removed and heights of the sidewall spacer 340 and the dielectric layer 350 are reduced, in accordance with some embodiments. In some embodiments, a planarization process is performed to remove the cap layers 335 and to reduce the heights of the sidewall spacer 340 and the dielectric layer 350. In some embodiments, the planarization process exposes the sacrificial gate electrodes 333. In some embodiments, the planarization process is a continuation of the process performed to planarize the dielectric layer 350.

Referring to FIG. 3D, the sacrificial gate electrodes 333 and the first gate dielectric layer 332 are removed to define gate cavities 355A, 355B, 355C and expose portions of the nanostructures 310A, 310B, 310C, in accordance with some embodiments. In some embodiments, an etch process is performed to remove the first gate dielectric layer 332 and the sacrificial gate electrodes 333. In some embodiments, the etch process is a wet etch process selective to the material of the sacrificial gate electrodes 333 and the material of the first gate dielectric layer 332.

Referring to FIG. 3E, the sacrificial semiconductor layers 320 are removed to define intermediate cavities 360 between the semiconductor material layers 315, and the cladding layer 326 is recessed to expose the sidewall liner 328 and a portion of the bottom liner 327, in accordance with some embodiments. In some embodiments, an etch process is performed to remove the sacrificial semiconductor layers 320 and to recess the cladding layer 326.

Referring to FIG. 3F, portions of the sidewall liner 328 are removed using the ion beam processing tool 100, in accordance with some embodiments. The ion beam processing tool 100 is configured to generate a tilted ion beam for removing portions of the sidewall liner 328. In some embodiments, the thickness of the sidewall liner 328 on the fin 325A is reduced, and the thickness of the sidewall liner 328 on the fin 325B is removed or the vertical portions of the sidewall liner 328 on the fin 325B are removed.

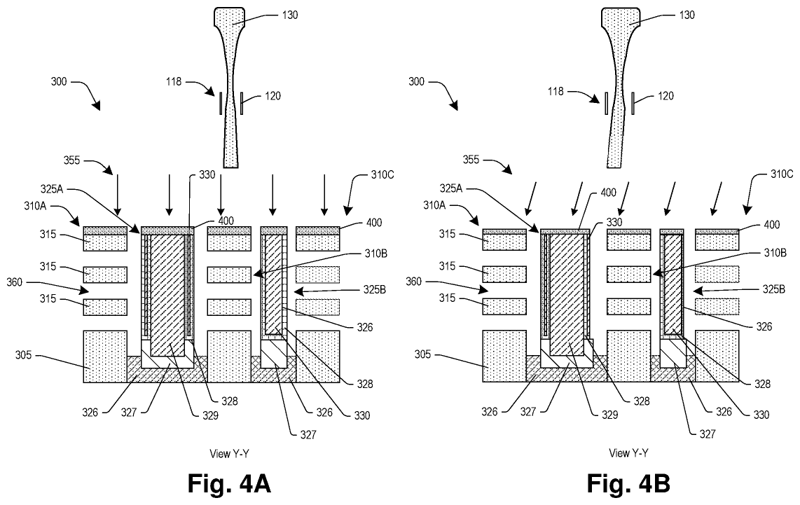

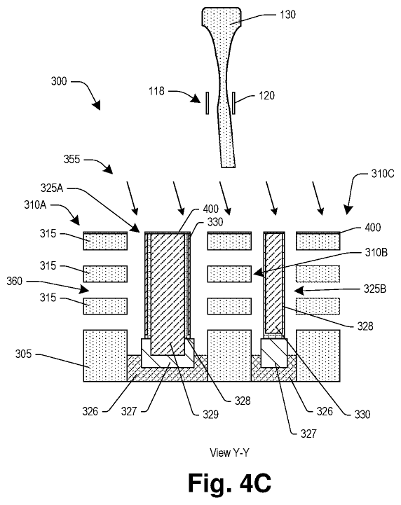

FIGS. 4A-4C illustrate a phased removal process performed by the ion beam processing tool 100 to remove the portions of the sidewall liner 328, in accordance with some embodiments. In some embodiments, the removal process comprises a cyclic process comprising a deposition phase illustrated in FIG. 4A, a first tilted removal phase illustrated in FIG. 4B, and a second tilted removal phase illustrated in FIG. 4C.

Referring to FIG. 4A, the ion beam processing tool 100 forms a protective layer 400 on upper surfaces of the fins 325A, 325B and on upper surfaces of the top semiconductor material layers 315 of the nanostructures 310A, 310B, 310C. In some embodiments, the protective layer 400 comprises a carbon layer formed using a plasma comprising CH₄ and H₂. In some embodiments, the protective layer 400 comprises a boron nitride (BN) polymer formed using a plasma comprising BCL₃ and N₂. In some embodiments, a thin vertical portion of the protective layer 400 may be formed on the sidewalls of the sidewall liner 328, but this vertical portion is omitted in FIG. 4A due to its small thickness compared to the horizontal portions formed over the upper surfaces of the fins 325A, 325B and the upper surfaces of the top semiconductor material layers 315. In some embodiments, the plates 120 of the beam deflector 118 are grounded such that no bias voltage is applied to the plates 120 as described in reference to FIG. 2A, and the neutralizer 114 is configured to fully charge exchange the ions in the ion beamlet 130, resulting in a neutral ion beam. The neutral ion beam promotes adsorption on the upper surfaces of the fins 325A, 325B and the upper surfaces of the top semiconductor material layers 315 while reducing the likelihood of surface damage or ion penetration.

Referring to FIG. 4B, a first tilted material removal phase is performed using the ion beam processing tool 100, and the first tilted material removal phase is configured to deflect the ion beam in a first direction. For example, the ion beam processing tool 100 is configured as described in reference to FIG. 2B by applying a bias voltage having a first polarity to the plates 120 of the beam deflector 118. In some embodiments, the first tilted material removal phase is performed using a plasma comprising BCl₃ for a sidewall liner 328 comprising hafnium oxide (HFOₓ). The etchant material may be selective to the material of the sidewall liner 328 to avoid etching or to significantly reduce an etch rate of the materials of the nanostructures 310A, 310B, 310C, such as the semiconductor material layers 315, the sidewall spacer 340, and the end spacers 342, and materials of the fins 325A, 325B, such as the cladding layer 326, the bottom liner 327, and the center portion 329. Other etch gasses may be employed for different materials of the sidewall liner 328. For purposes of illustration, the amount of material removal illustrated in FIG. 4B is exaggerated. In some embodiments, a portion of the protective layer 400 is removed during the first tilted material removal phase, but sufficient thickness of the protective layer 400 remains to mitigate damage to the nanostructures 310A, 310B, 310C. In some embodiments, the neutralizer 114 is configured to partially neutralize the ion beamlet 130, where the neutral to charged ion ratio may be controlled to affect the etch rate of the sidewall liner 328, the consumption rate of the protective layer 400, and to avoid faceting of the fins 325A, 325B or the nanostructures 310A, 310B, 310C.

Referring to FIG. 4C, a second tilted material removal phase is performed using the ion beam processing tool 100 configured to deflect the ion beam in a second direction opposite the first direction. For example, the ion beam processing tool 100 is configured as described in reference to FIG. 2C by applying a bias voltage having a second polarity to the plates 120 of the beam deflector 118. In some embodiments, the second tilted material removal phase is performed using a plasma comprising BCl₃ for a sidewall liner 328 comprising hafnium oxide (HFOₓ). The etchant material may be selective to the material of the sidewall liner 328 to avoid etching or to significantly reduce an etch rate of the materials of the nanostructures 310A, 310B, 310C, such as the semiconductor material layers 315, the sidewall spacer 340, and the end spacers 342, and materials of the fins 325A, 325B, such as the cladding layer 326, the bottom liner 327, and the center portion 329. Other etch gasses may be employed for different materials of the sidewall liner 328. For purposes of illustration, the amount of material removal illustrated in FIG. 4C is exaggerated. In some embodiments, a portion of the protective layer 400 is removed during the second tilted material removal phase, but sufficient thickness of the protective layer 400 remains to mitigate damage to the nanostructures 310A, 310B, 310C. In some embodiments, the neutralizer 114 is configured to partially neutralize the ion beamlet 130, where the neutral to charged ion ratio may be controlled to affect the etch rate of the sidewall liner 328, the consumption rate of the protective layer 400, and to avoid faceting of the fins 325A, 325B or the nanostructures 310A, 310B, 310C.

In some embodiments, the phases described in FIGS. 4A-4C are repeated until the desired degree of material removal of the sidewall liner 328 is achieved. The parameters of the deposition and material removal process may change between iterations of the phases. For example, the deposition phase may be shortened for later iterations to maintain the thickness of the protective layer 400 without the protective layer 400 becoming too thick. After completion of the iterative etch process, the protective layer 400 may be removed, for example, using a selective etch process.

In some embodiments, the target 116 may be rotated during at least one of the deposition phase or the tilted material removal phases, or the target 116 may be maintained in a horizontal position during the deposition phase and the tilted material removal phases. Using the beam deflector 118 to provide a tilted material removal phase reduces pitch walking and etch asymmetry issues associated with a vertical etch using a tilted target. In some embodiments, the target may be tilted and rotated in combination with the beam tilting using the beam deflector 118 to provide a more flexible process window.

In some embodiments, the entire vertical portions of the sidewall liner 328 are removed from one or both of the fins 325A, 325B. For example, in FIG. 3F, the vertical portions of the sidewall liner 328 are removed from the fin 325B, but only partially removed from the fin 325A. Removing the portions of the sidewall liner 328 increases the dimensions of the gate cavities 355A, 355B, 355C by increasing the spacing, C1, between the fin 325A and the nanostructure 310A, the spacing, C2, between the fin 325A and the nanostructure 310B, the spacing, C3, between the fin 325B and the nanostructure 310B, and the spacing, C4, between the fin 325B and the nanostructure 310C.

Referring to FIG. 3G, gate structures 365A, 365B, 365C are formed in the gate cavities 355A, 355B, 355C, in accordance with some embodiments. In some embodiments, the gate structures 365A, 365B, 365C comprises a gate dielectric layer, a gate electrode layer, and other suitable layers. In some embodiments, the gate dielectric layer comprises a high-k dielectric material. In some embodiments, the gate electrode layer comprises a metal fill layer. In some embodiments, the metal fill layer comprises tungsten (W) or other suitable material. The gate dielectric layer, gate electrode layer, and other suitable layers of the gate structures 365A, 365B, 365C may be deposited by at least one of atomic layer deposition (ALD), physical vapor deposition (PVD), CVD, or other suitable processes. According to some embodiments, a planarization process is performed to remove portions of the material forming the gate structures 365A, 365B, 365C positioned over the dielectric layer 350 and portions of the dielectric layer 350 and the sidewall spacer 340 to expose the upper surfaces of the fins 325A, 325B.

Referring to FIG. 3H, cap layers 370 are formed over the gate structures 365A, 365B, 365C, in accordance with some embodiments. In some embodiments, the cap layers 370 are formed using a deposition process. In some embodiments, the cap layers 370 comprise dielectric materials. In some embodiments, the cap layers 370 comprise silicon and nitrogen, silicon and oxygen, or other suitable materials.

In some embodiments, removing a portion of or all of the sidewall liner 328 increases the size of the gate cavities 355A, 355B, 355C, thereby increasing the process window for forming the gate structures 365A, 365B, 365C. Removing portions of the sidewall liner 328 also reduces capacitance. Using the beam deflector 318 to perform the tilted etch process reduces the likelihood of damage to the nanostructures 310A, 310B, 310C and serves to reduce issues with pitch walking and etch asymmetry.

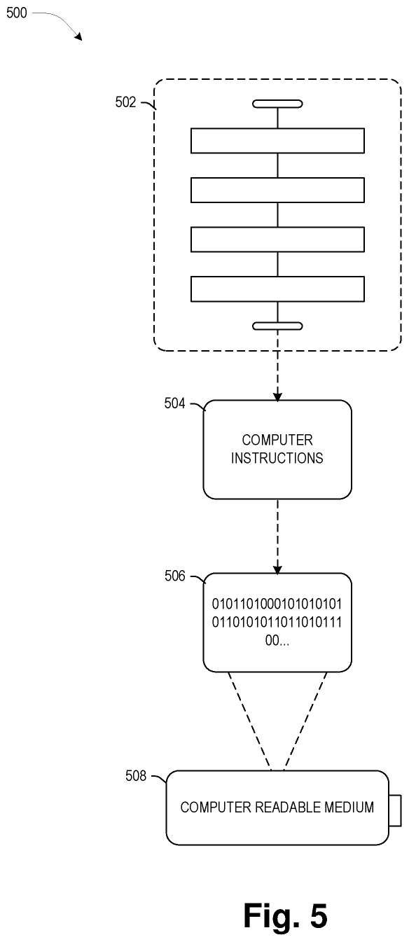

FIG. 5 illustrates an exemplary computer-readable medium, according to some embodiments. One or more embodiments involve a computer-readable medium comprising processor-executable instructions configured to implement one or more of the techniques presented herein. An exemplary computer-readable medium is illustrated in FIG. 5, wherein the embodiment 500 comprises a computer-readable medium 506 (e.g., a CD-R, DVD-R, flash drive, a platter of a hard disk drive, etc.), on which is encoded computer-readable data 504. This computer-readable data 504 in turn comprises a set of processor-executable computer instructions 502 that when executed are configured to facilitate operations according to one or more of the principles set forth herein, such as operations of the controller 105. In some embodiments 500, the processor-executable computer instructions 502 are configured to facilitate performance of a method 501, such as at least some of the aforementioned method(s). In some embodiments, the processor-executable computer instructions 502 are configured to facilitate implementation of a system, such as at least some of the one or more aforementioned system(s). Many such computer-readable media may be devised by those of ordinary skill in the art that are configured to operate in accordance with the techniques presented herein.

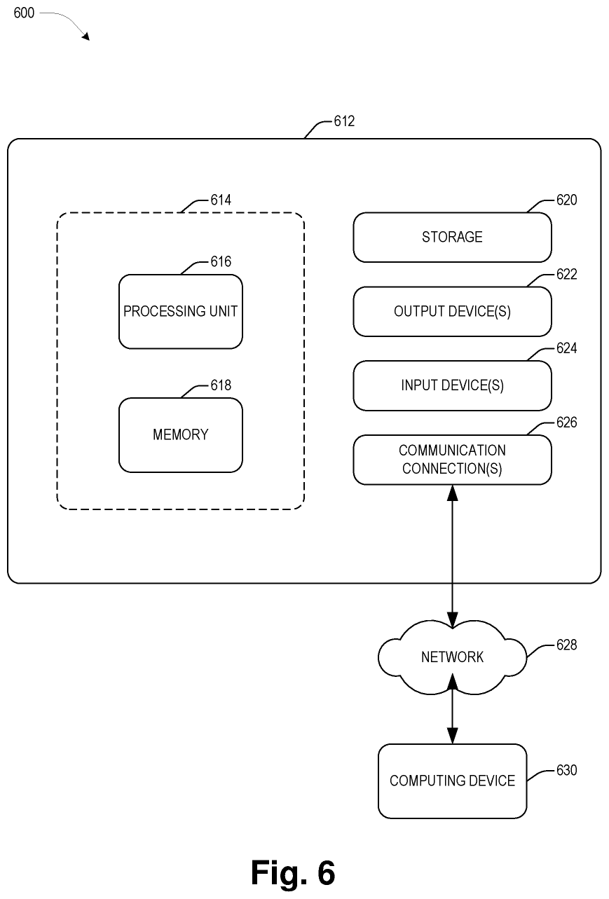

FIG. 6 illustrates an example computing environment wherein one or more of the provisions set forth herein may be implemented, according to some embodiments. FIG. 6 and the following discussion provide a brief, general description of a suitable computing environment to implement embodiments of one or more of the provisions set forth herein. The computing environment of FIG. 6 is only one example of a suitable computing environment and is not intended to suggest any limitation as to the scope of use or functionality of the computing environment. Example computing devices include, but are not limited to, personal computers, server computers, hand-held or laptop devices, mobile devices (such as mobile phones, Personal Digital Assistants (PDAs), media players, and the like), multiprocessor systems, consumer electronics, mini computers, mainframe computers, distributed computing environments that include any of the above systems or devices, and the like.

Although not required, embodiments are described in the general context of “computer readable instructions” being executed by one or more computing devices. Computer readable instructions may be distributed via computer readable media (discussed below). Computer readable instructions may be implemented as program modules, such as functions, objects, Application Programming Interfaces (APIs), data structures, and the like, that perform particular tasks or implement particular abstract data types. Typically, the functionality of the computer readable instructions may be combined or distributed as desired in various environments.

FIG. 6 depicts an example of a system 600 comprising a computing device 602 configured as a controller to implement embodiments provided herein. In some configurations, computing device 602 includes at least one processing unit 606 and memory 608. Depending on the exact configuration and type of computing device, memory 608 may be volatile (such as random access memory (RAM), for example), non-volatile (such as read-only memory (ROM), flash memory, etc., for example) or some combination of the two. This configuration is illustrated in FIG. 6 by dashed line 604.

In some embodiments, computing device 602 may include additional features and/or functionality. For example, computing device 602 may also include additional storage (e.g., removable and/or non-removable) including, but not limited to, magnetic storage, optical storage, and the like. Such additional storage is illustrated in FIG. 6 by storage 610. In some embodiments, computer readable instructions to implement one or more embodiments provided herein may be in storage 610. Storage 610 may also store other computer readable instructions to implement an operating system, an application program, and the like. Computer readable instructions may be loaded in memory 608 for execution by processing unit 606, for example.

The term “computer readable media” as used herein includes computer storage media. Computer storage media includes volatile and nonvolatile, removable and non-removable media implemented in any method or technology for storage of information such as computer readable instructions or other data. Memory 608 and storage 610 are examples of computer storage media. Computer storage media includes, but is not limited to, RAM, ROM, electrically erasable programmable read-only memory (EEPROM), flash memory or other memory technology, CD-ROM, Digital Versatile Disks (DVDs) or other optical storage, magnetic cassettes, magnetic tape, magnetic disk storage or other magnetic storage devices, or any other medium which can be used to store the desired information and which can be accessed by computing device 602. Any such computer storage media may be part of computing device 602.

Computing device 602 may also include communication connection(s) 616 that allows computing device 602 to communicate with other devices. Communication connection(s) 1516 may include, but is not limited to, a modem, a Network Interface Card (NIC), an integrated network interface, a radio frequency transmitter/receiver, an infrared port, a universal serial bus (USB) connection, or other interfaces for connecting computing device 602 to other computing devices. Communication connection(s) 616 may include a wired connection or a wireless connection. Communication connection(s) 616 may transmit and/or receive communication media.

The term “computer readable media” may include communication media. Communication media typically embodies computer readable instructions or other data in a “modulated data signal” such as a carrier wave or other transport mechanism and includes any information delivery media. The term “modulated data signal” may include a signal that has one or more of its characteristics set or changed in such a manner as to encode information in the signal.

Computing device 602 may include input device(s) 614 such as keyboard, mouse, pen, voice input device, touch input device, infrared cameras, video input devices, and/or any other input device. Output device(s) 612 such as one or more displays, speakers, printers, and/or any other output device may also be included in computing device 602. Input device(s) 614 and output device(s) 612 may be connected to computing device 602 via a wired connection, wireless connection, or any combination thereof. In some embodiments, an input device or an output device from another computing device may be used as input device(s) 614 or output device(s) 612 for computing device 602.

Components of computing device 602 may be connected by various interconnects, such as a bus. Such interconnects may include a Peripheral Component Interconnect (PCI), such as PCI Express, a Universal Serial Bus (USB), firewire (IEEE 1394), an optical bus structure, and the like. In some embodiments, components of computing device 602 may be interconnected by a network. For example, memory 608 may be comprised of multiple physical memory units located in different physical locations interconnected by a network.

Those skilled in the art will realize that storage devices utilized to store computer readable instructions may be distributed across a network. For example, a computing device 620 accessible via a network 618 may store computer readable instructions to implement one or more embodiments provided herein. Computing device 602 may access computing device 620 and download a part or all of the computer readable instructions for execution. Alternatively, computing device 602 may download pieces of the computer readable instructions, as needed, or some instructions may be executed at computing device 602 and some at computing device 620.

In some embodiments, an ion beam processing tool includes a plasma source, a grid arrangement positioned proximate the plasma source to generate an ion beam, a beam deflector positioned adjacent the grid arrangement, and a controller configured to control the beam deflector to deflect the ion beam to generate a tilted ion beam.

In some embodiments, a method includes generating an ion beam, directing the ion beam at a target, deflecting the ion beam in a first direction to remove a first portion of material from the target, and deflecting the ion beam in a second direction different than the first direction to remove a second portion of material from the target.

In some embodiments, a method for forming a semiconductor structure includes forming a first nanostructure and forming a second nanostructure. A first fin is formed between the first nanostructure and the second nanostructure. A sacrificial gate structure is formed over the first nanostructure, the second nanostructure, and the first fin. A portion of the sacrificial gate structure is removed to form a first gate cavity over a portion of the first nanostructure and expose a first sidewall of the first fin and to form a second gate cavity over a portion of the second nanostructure and expose a second sidewall of the first fin. An ion beam processing tool is employed. The ion beam processing tool includes a beam deflector configured to perform a tilted etch process to remove a first portion of the first fin along the first sidewall and to remove a second portion of the first fin along the second sidewall. A first gate structure is formed in the first gate cavity and a second gate structure in the second gate cavity after the tilted etch process.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An ion beam processing tool, comprising:
a plasma source;
a grid arrangement positioned proximate the plasma source to generate an ion beam;
a beam deflector positioned adjacent the grid arrangement; and
a controller configured to control the beam deflector to deflect the ion beam to generate a tilted ion beam.

2. The ion beam processing tool of claim 1, wherein:
the beam deflector comprises plates.

3. The ion beam processing tool of claim 2, wherein:
the controller is configured to apply a first bias voltage to the plates to deflect the ion beam in a first direction and apply a second bias voltage to the plates having a polarity opposite the first bias voltage to deflect the ion beam in a second direction opposite the first direction.

4. The ion beam processing tool of claim 1, wherein:
the grid arrangement comprises an extraction grid and an acceleration grid, and
the beam deflector comprises plates between the extraction grid and the acceleration grid along a path of the ion beam.

5. The ion beam processing tool of claim 1, wherein:
the grid arrangement comprises an acceleration grid and a deceleration grid, and
the beam deflector comprises plates disposed after the deceleration grid along a path of the ion beam.

6. The ion beam processing tool of claim 5, wherein:
the grid arrangement comprises a neutralizer, and
the plates are between the deceleration grid and the neutralizer along the path of the ion beam.

7. A method, comprising:
generating an ion beam;
directing the ion beam at a target;
deflecting the ion beam in a first direction to remove a first portion of material from the target; and
deflecting the ion beam in a second direction different than the first direction to remove a second portion of material from the target.

8. The method of claim 7, wherein:
deflecting the ion beam in the first direction comprises applying a first bias voltage to plates of a beam deflector adjacent the ion beam, and
deflecting the ion beam in the second direction comprises applying a second bias voltage to the plates different than the first bias voltage.

9. The method of claim 7, comprising:
forming a protective layer over the target prior to deflecting the ion beam in the first direction.

10. The method of claim 9, wherein forming the protective layer comprises:
grounding plates of a beam deflector adjacent the ion beam; and
performing a charge exchange process to neutralize the ion beam.

11. The method of claim 9, comprising:
iteratively repeating the forming of the protective layer, the deflecting of the ion beam in the first direction to remove the first portion of material from the target, and the deflecting of the ion beam in the second direction to remove the second portion of material from the target.

12. The method of claim 7, wherein:
the target comprises a semiconductor wafer.

13. A method for forming a semiconductor structure, comprising:
forming a first nanostructure;
forming a second nanostructure;
forming a first fin between the first nanostructure and the second nanostructure;
forming a sacrificial gate structure over the first nanostructure, the second nanostructure, and the first fin;
removing a portion of the sacrificial gate structure to form a first gate cavity over a portion of the first nanostructure and expose a first sidewall of the first fin and to form a second gate cavity over a portion of the second nanostructure and expose a second sidewall of the first fin;
employing an ion beam processing tool comprising a beam deflector configured to perform a tilted etch process to remove a first portion of the first fin along the first sidewall and to remove a second portion of the first fin along the second sidewall; and
forming a first gate structure in the first gate cavity and a second gate structure in the second gate cavity after the tilted etch process.

14. The method of claim 13, wherein performing the tilted etch process comprises:
deflecting an ion beam of the ion beam processing tool in a first direction by applying a first bias voltage to plates of the beam deflector adjacent the ion beam to remove the first portion of the first fin, and
deflecting the ion beam in a second direction by applying a second bias voltage to the plates different than the first bias voltage to remove the second portion of the first fin.

15. The method of claim 14, comprising:
forming a protective layer over the first nanostructure, the second nanostructure, and the first fin prior to deflecting the ion beam in the first direction.

16. The method of claim 15, wherein the protective layer comprises at least one of carbon or boron nitride.

17. The method of claim 15, wherein forming the protective layer comprises:
grounding the plates of the beam deflector; and
performing a charge exchange process to neutralize the ion beam.

18. The method of claim 15, comprising:
iteratively repeating the forming of the protective layer, the deflecting of the ion beam in the first direction to remove the first portion of the first fin, and the deflecting of the ion beam in the second direction to remove the second portion of the first fin.

19. The method of claim 13, wherein:
the first portion of the first fin comprises a high-k dielectric material.

20. The method of claim 13, wherein:
the first fin comprises a high-k sidewall liner, and the first portion of the first fin comprises an entire thickness of the high-k sidewall liner.
